(19) United States
(12) Patent Application Publication
(10) Pub. No.: US 2011/0163784 A1
(43) Pub. Date: Jul. 7, 2011

(54) FRACTIONAL FREQUENCY DIVIDER

(76) Inventor: Sebastian Loeda, Edinburgh (GB)

(21) Appl. No.: 12/989,704

(22) PCT Filed: Mar. 25, 2009
(86) PCT No.: PCT/GB2009/050282

§ 371 Date: Jan. 7, 2011

(30) Foreign Application Priority Data
Apr. 29, 2008 (GB) 0807749.7

(51) Int. Cl. H03K 21/00

(52) U.S. Cl. 327/117

(57) ABSTRACT

A fractional-n frequency divider that overcomes the presence of so-called dead zones in known frequency divider circuits, n divider cells (3) are connected so as to form a ripple counter (n being an integer greater than or equal to two) and an output multiplexer (22) is provided with a clock signal (24) and an inverted clock signal (25) by the nth divider cell. A polarity circuit (26) generates a polarity signal (23) which clocks the output multiplexer (22) so as to controllably combine the clock signal and the inverted clock signal to produce an output signal (5). A toggle signal (9) toggles between a first and a second integer division configuration so as to provide for fractional divisional outputs therebetween. With n ⅔ divider cells (3) the division ratio therefore can take any fractional value that satisfies the following inequality 2 (n−1) less than or equal to division ratio less than or equal to 2 (n+1)−1.

The present invention relates to the field of electronic circuits and in particular to fractional-n frequency dividers.

Most communication receivers implement a heterodyne frequency translation, whereby the high frequency component signals received at an antenna are mixed down to lower frequency signals. Generally the receiver is tuned to down-convert a particular frequency band by changing the local oscillator (LO) frequency.

The LO frequency is typically achieved with a phase-lock loop (PLL) that is locked to a fixed low frequency reference clock. Changing the division ratio of the feedback divider in the PLL will change the LO frequency. Typical PLL implementations known to those skilled in the art are limited to integer division ratios of a set frequency. Unfortunately, useful frequency bands are seldom at integer divisions ratios of a common frequency. Non-integer (fractional) division ratios of the feedback divider are therefore required if the receiver is to tune to multiple, useful frequency bands, using the same PLL.

A number of fractional feedback divider implementations already exist in the literature. Of greatest relevance to the following described invention are the fractional-n frequency dividers described by Vaucher et al in their IEEE Journal of Solid-State Circuits, Volume 35, No. 7, July 2000 paper entitled “A Family of Low-Power Truly Modular Programmable Dividers in Standard 0.35-μm CMOS Technology”. For ease of reference a schematic representation of two fractional-n frequency dividers, 1 and 2, described by Vaucher et al are presented in FIGS. 1(a) and 1(b), respectively.

The fractional-n frequency divider 1 of FIG. 1(a) comprises a chain of n, ⅔ divider cells 3 connected like a ripple counter so as to divide an input signal 4 of frequency Fᵢₙ to produce output signal 5, having frequency Fₒᵤₜ. Once in a division period, the last cell 3 (n) on the chain generates the signal modₙ₋₁. This signal then propagates “up” the chain, being reclocked by each cell 3 along the way. An active mod signal enables a cell 3 to divide by 3 (once in a division cycle), provided that its clock pₙ is set to 1. Division by three adds one extra period of each cell's 3 input signal to the period of the output siynal 5. Hence, a chain of n ⅔ cells 3 provides an output signal 5 with a period of:

Tₒᵤₜ=(2ⁿ+2ⁿ⁻¹pₙ₋₁+2ⁿ⁻²pₙ₋₂+ . . . +2p₁+p₀)Tᵢₙ (1)

With n divider cells 3 the division range of the fractional-n frequency divider 1 is thus within the range:

Minimum division ratio=2ⁿ (2)

Maximum division ratio=2ⁿ⁺¹−1 (3)

The operation of the architecture is based on the direct relation between the performed division ratio and a bus programmed division word D^{k}={pₙ₋₁, pₙ₋₂, . . . , p₁, p₀} employed to clock each of the individual divider cells 3. By way of example let us consider the case when the fractional-n frequency divider 1 comprises seven divider cells 3. By appropriate setting of the bus programmed division word D^{k}={p₆, p₅, p₄, p₃, p₂, p₁, p₀}, an integer division ratio k is achieved. The minimum division ratio available is 128, when the bus programmed division word takes appropriate D¹²⁸ values while the maximum division ratio available is 255, for appropriate D²⁵⁵ values.

A fractional division output signal 5 may be achieved by controlled toggling between appropriate bus programmed division words D^{k} and D^{k+1}, at the positive clock edge of the fractional-n frequency divider 1 output. The integer part of the division ratio will be D^{k}, while the fractional part of the division will be set by the ratio between the number of divisions by D^{k}, and the number of divisions by D^{k+1}. For example an equal number of D²⁰⁸ divisions and D²⁰⁹ divisions will achieve an effective fractional division by 208.5.

An important point to note is that by taking the output signal 5 as the Fₒᵤₜ signal between the first and second divider cells 3 results in the output operating at the frequency of the second divider cell 3. This output source is inherently susceptible to detrimental harmonics and fractional spurious tones induced through the toggling of the output signal 5

From the above discussion it can be seen that the output signal 5 of the fractional-n frequency divider 1 of FIG. 1(a) comprising seven divider cells 3 is limited to the divisional operational range of 128 to 255. In a similar manner, a fractional-n frequency divider 1 comprising eight divider cells 3 is limited to the divisional operational range of 256 to 511. As a result the architecture of the fractional-n frequency divider 1 exhibits a number of frequency “dead zones” i.e. frequency bands wherein the phase-lock loop implementation can not tune the local oscillator frequency e.g. between 255 and 256. This is a result of the fact that in order to operate in these “dead zones” the divider 1 is required to attempt to toggle between the bus programmed division word for the maximum divisional ratio of n−1 divider cells 3 and the bus programmed division word for the minimum divisional ratio of n divider cells 3. The output of the divider 1 must also simultaneously switch between a Clkₙ₋₁ and Clkₙ output. This presents significant timing issues as the edge of the output of the divider 1 sets which clock should be output, and these two clocks may be out of-phase.

One known solution to overcome these frequency “dead zones” is achieved by employing the architecture of the fractional-n frequency divider 2 shown in FIG. 1(b).

In a similar manner to fractional-n frequency divider 1 the fractional-n frequency divider 2 comprises a chain of n, ⅔ divider cells 3 connected like a ripple counter so as to divide the input signal 4 of frequency Fᵢₙ to produce output signal 5, having frequency Fₒᵤₜ. A plurality of OR gates 6 are also incorporated so as to allow the effective length n′ of the fractional-n frequency divider 2 to be predetermined.

The effective length n′ is the number of the ⅔ divider cells 3 that influence the division cycle. By setting the mod input of a certain ⅔ divider cell 3 to the active level the influence of all divider cells 3 to the right of that cell are overruled. As a result the fractional-n frequency divider 1 behaves as if it has been shortened, with the effective length n′ corresponding to the index of the most significant (and active) bit of the programmed division word. With this additional logic the division range becomes:

Minimum division ratio=2^{n′min} (4)

Maximum division ratio=2ⁿ⁻¹−1 (5)

The minimum and maximum division ratios can be set independently, by choice of n′ₘᵢₙ and n, respectively. However, the architecture of the fractional-n frequency divider 2 is such that the inherent problems of fractional spurious tones being imparted onto the output signal 5 still remain.

One solution to the existence of problematic frequency spurious tones is described by Rogers et al in their IEEE Journal of Solid-State Circuits, Volume 40, No. 3, March 2005 paper entitled “A Multiband ΔΣ Fractional-n Frequency Synthesizer for a MIMO WLAN Transceiver RFIC”. Here a Sigma Delta modulator is employed to toggle between successive bus programmed division words so as to achieve a finer step size and lower levels of in band phase noise.

It is therefore an object of aspects of the present invention to provide a fractional-n frequency divider that obviates or mitigates one or more of the above limitations of the prior art devices.

### SUMMARY OF INVENTION

According to a first aspect of the present invention there is provided a fractional-n frequency divider comprising n divider cells connected so as to form a ripple counter, n being an integer greater than or equal to two, an output multiplexer that is provided with a clock signal (Clkₙ) and an inverted clock signal (/Clkₙ) by the nth divider cell, and a polarity circuit that provides a means for generating a polarity signal, wherein the polarity signal is employed to clock the output multiplexer so as to controllably combine clock signal (Clkₙ) and an inverted clock signal (/Clkₙ) to produce an output signal (Fₒᵤₜ).

Most preferably the polarity circuit comprises a latch, the latch having a first configuration whereby the clock signal (Clkₙ) is provided as an input signal and the clock signal output from the n−1 divider cell (Clkₙ₋₁) is provided as a latch clocking signal. With this first configuration the polarity signal flops between a logic low state and a logic high state in response to the clock signal output from the n−1 divider cell (Clkₙ₋₁) such that polarity signal effectively comprises a phase delayed clock signal (Clkₙ) resulting in the output signal (Fₒᵤₜ) replicating the clock signal output from the n−1 divider cell (Clkₙ₋₁).

Preferably the latch is clocked by an inverted clock signal output from the n−1 divider cell (/Clkₙ₋₁) . This arrangement causes the polarity signal to flop in response to the negative edge of the clock signal output from the n−1 divider cell (Clkₙ₋₁) .

Preferably the fractional-n frequency divider further comprises a feedback multiplexer located within the feedback link between the nth divider cell and the n−1 divider cell wherein the feedback multiplexer provides a means for switching the fractional-n frequency divider between a first configuration, wherein the feedback to the n−1 divider cell is set to logic high, and a second configuration, wherein the feedback to the n−1 divider cell is provided by the nth divider cell.

Preferably the polarity circuit further comprises a polarity circuit multiplexer wherein the polarity circuit multiplexer provides a means for switching polarity circuit from the first configuration to a second configuration, wherein the polarity signal is fed back to provide the input signal to the latch. In this configuration the polarity signal is prevented from flopping between the logic low state and a logic high state.

Preferably the polarity circuit further comprises a first and second polarity AND gates configured to provide a first and second input to the polarity circuit multiplexer.

Most preferably the fractional-n frequency divider further comprises a hold circuit that provides a means for generating a hold signal that is employed to control the configuration of the polarity circuit.

Most preferably the hold signal is also employed to control the configuration of the fractional-n frequency divider via the feedback multiplexer.

Importantly is should be noted that with the fractional-n frequency divider and the polarity circuit in their respective second configurations the output signal (Fₒᵤₜ) replicates that of n divider cells connected so as to form a ripple counter.

Most preferably the fractional-n frequency divider further comprises a multiplexer associated with each n divider cells wherein the multiplexers provide a means of switching between at least two clock signals for the associated n divider cells.

Preferably the fractional-n frequency divider further comprises an nth divider cell AND gate located between the nth divider cell and its associated multiplexer.

Most preferably the fractional-n frequency divider is provided with at least two implementing division code words, D^{k-1} and D^{k}′ which determine a first and a second integer division configuration of the fractional-n frequency divider.

Preferably each implementing division code word comprises divisional code signals Dₙ, Dₙ₋₁, Dₙ₋₂ . . . D₂, D₁, and D₀.

Preferably first and second inputs to each of the multiplexers associated with n divider cells are provided with divisional code signals D^{k-1}ₙ₋₁ and D^{k}ₙ₋₁, respectively.

Preferably a first and second input to the nth divider cell AND gate is provided by divisional code signal D^{k}ₙand the output of the multiplexer associated with the nth divider cell, respectively.

Most preferably a toggle signal is employed to control the settings of the multiplexer associated with each n divider cells. In this way the fractional-n frequency divider can be configured to toggle between the first and second integer division configurations. It is the controlled toggling of these two configurations that provides for fractional divisional outputs between D^{k-1} and D^{k}. With n ⅔ divider cells the division ratio therefore can take any fractional value that satisfies the following inequality 2ⁿ⁻¹≦division ratio≦2ⁿ⁺¹−1.

Preferably the hold circuit comprises an XOR gate having a first input provided by a three input AND Gate and a second input provided by divisional code signal D^{k}ₙ.

Preferably the inputs to the three input AND Gate comprises divisional code signals D^{k}₀ to D^{k}ₙ₋₁, the toggle signal and an inverted divisional code signal D^{k}ₙ (/D^{k}ₙ).

Preferably the first polarity AND gate is provide with a first input corresponding to the polarity signal and a second input corresponding to the inverted divisional code signal D^{k}ₙ (/D^{k}ₙ).

Preferably the second polarity AND gate is provide with a first input corresponding to the clock signal (Clkₙ) and a second input corresponding to the inverted divisional code signal D^{k}ₙ (/D^{k}ₙ).

According to a second aspect of the present invention there is provided a method of frequency dividing a signal Fᵢₙ, the method comprising the steps of:
1) passing the signal Fᵢₙ through n divider cells connected so as to form a ripple counter;
2) generating a clock signal (Clkₙ) and an inverted clock signal (/Clkₙ) from the nth divider cell; and
3) producing an output signal Fₒᵤₜ by controllably combining the clock signal (Clkₙ) and the inverted clock signal (/Clkₙ).

Most preferably the step of producing the output signal Fₒᵤₜ comprises the steps of:
1) providing a logic high feedback between the nth and n−1 divider cells; and
2) flopping between the clock signal (Clkₙ) and the inverted clock signal (/Clkₙ) in response to a clock signal generated by an output from a n−1 divider cell (Clkₙ₋₁).

This results in the output signal (Fₒᵤₜ) replicating the clock signal output from the n−1 divider cell (Clkₙ₋₁).

Most preferably the step of flopping between the clock signal (Clkₙ) and the inverted clock signal (/Clkₙ) occurs in response to the negative edge of the clock signal output from the n−1 divider cell (Clkₙ₋₁).

Alternatively, the step of producing the output signal Fₒᵤₜ comprises the steps of:
3) providing a feedback link to the n−1 divider cell directly from the nth divider cell; and
4) preventing flopping between the clock signal (Clkₙ) and the inverted clock signal (/Clkₙ).

This results in the output signal (Fₒᵤₜ) replicating the clock signal output from n divider cell (Clkₙ).

Most preferably the method of frequency dividing the signal Fᵢₙ further comprises the step of providing at least two implementing division code words, D^{k-1} and D^{k′} which determine a first and a second integer division configuration of the fractional-n frequency divider.

Most preferably the method of frequency dividing the signal Fᵢₙ further comprises the step of toggling between first and a second integer division configuration of the fractional-n frequency divider. It is the controlled toggling of these two configurations that provides for fractional divisional outputs between D^{k-1} and D^{k}. e.g. With n ⅔ divider cells the division ratio therefore can take any fractional value that satisfies the following inequality 2ⁿ⁻¹≦division ratio≦2ⁿ⁺¹−1.

### BRIEF DESCRIPTION OF DRAWINGS

Aspects and advantages of the present invention will become apparent upon reading the following detailed description and upon reference to the following drawings in which:

FIG. 1 presents a schematic representation of:
(a) a first prior art fractional-n frequency divider; and
(b) a second prior art fractional-n frequency divider;

FIG. 2 presents a schematic representation of a fractional-n frequency divider in accordance with an aspect of the present invention;

FIG. 3 presents a table of division code words for a number of configurations of the fractional-n frequency divider of FIG. 2;

FIG. 4 presents a schematic representation of the fractional-n frequency divider of FIG. 2 configured to provide a fractional output between 128 and 129;

FIG. 5 presents a schematic timing diagram for the signals of the fractional-n frequency divider of FIG. 2 configured to provide an output that corresponds to Fᵢₙ/k, where k is an integer between 2ⁿ⁻¹ and 2ⁿ−1;

FIG. 6 presents a schematic representation of the fractional-n frequency divider of FIG. 2 configured to provide a fractional output between 255 and 256;

FIG. 7 presents a schematic timing diagram for the signals of the fractional-n frequency divider of FIG. 2 configured to provide an output that corresponds to Fᵢₙ/255.x;

FIG. 8 presents a schematic representation of the fractional-n frequency divider of FIG. 2 configured to provide a fractional output between 256 and 257; and

FIG. 9 presents a schematic representation of the fractional-n frequency divider of FIG. 2 configured to provide a fractional output between 510 and 511.

### DETAILED DESCRIPTION

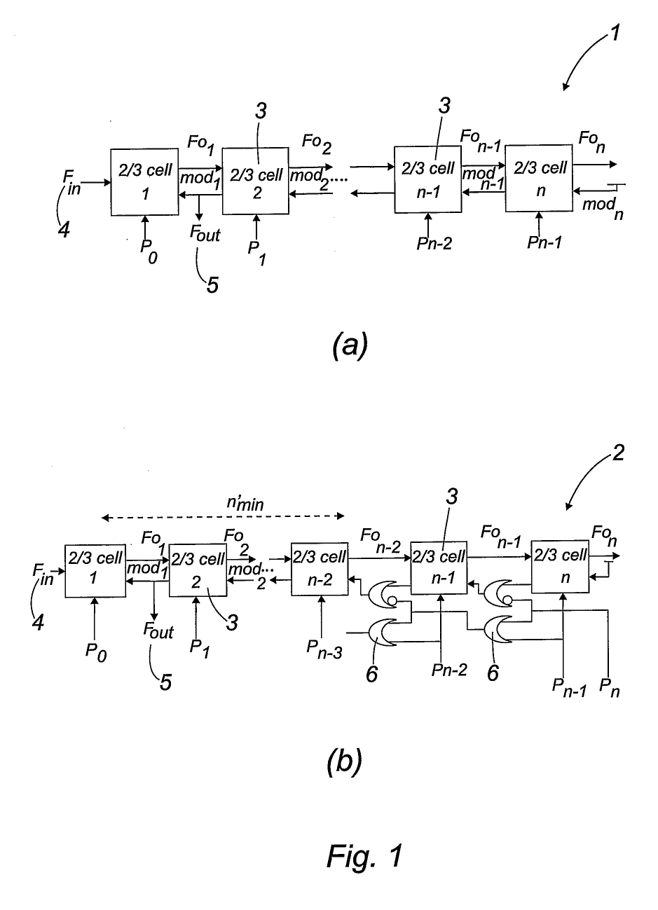

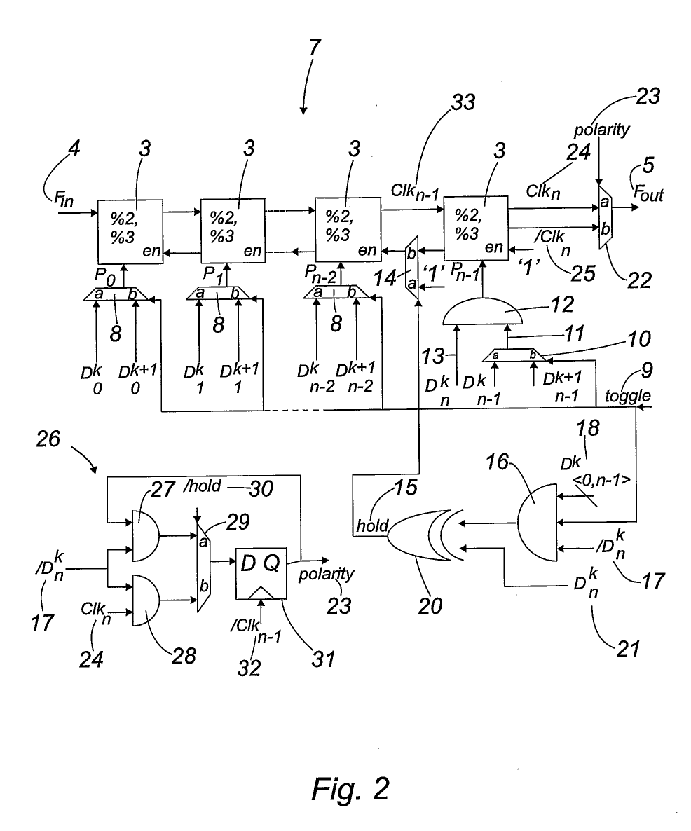

Aspects and embodiments of the present invention will now be described with reference to FIGS. 2 to 9.

In particular, FIG. 2 presents a schematic representation of a fractional-n frequency divider 7 in accordance with an aspect of the present invention. In a similar manner to the prior art system presented in FIG. 1(a), the fractional-n frequency divider 7 comprises a chain of n, ⅔ divider cells 3 connected so as to form a ripple counter, thus acting to divide an input signal 4 of frequency Fᵢₙ to produce output signal 5, having frequency Fₒᵤₜ.

Each of the ⅔ divider cells 3 are modulated in a similar manner to that described above. In particular, the first to the n−1 divider cells 3 are modulated via dedicated multiplexers 8. Each multiplexer 8 is arranged to simultaneously toggle between two channels, “a” and “b”, respectively, under the control of a toggle signal 9 so as to provide clock signals p₀ to Pₙ₋₂, respectively. As a result, when the toggle signal is logic low, clock signals p₀ to pₙ₋₂ correspond to those signals transmitted by the a-channels, while when the toggle signal is logic high, clock signals p₀ to pₙ₋₂ correspond to those signals transmitted by the b-channels.

The toggle signal 9 is also used to switch the output of a first nth divider multiplexer 10 between corresponding “a” and “b” channels. However, instead of clocking the nth divider cell 3 directly, the output of nth divider multiplexer 10 provides a first input signal 11 for an nth divider AND gate 12. A second input signal 13 is also provided to the nth divider AND gate 12. It is the output signal from the nth divider AND gate 12 which is then employed to produce clock signal pₙ₋₁.

As can be seen from FIG. 2, a feedback multiplexer 14 is located within the feedback link between the nth divider cell and the n−1 divider cell. The function of the feedback multiplexer 14 is to select whether the ripple feedback to the n−1 divider cell is provided by the nth divider cell, via the b-channel, or is simply set to logic high via the a-channel. Selection between the a-channel and the b-channel of the feedback multiplexer 14 is controlled by a “hold” signal 15 that is generated as follows.

From FIG. 2 it can be seen that toggle signal 9 provides a first input to a three input AND gate 16. An inverted D^{k}ₙ division code signal (/D^{k}ₙ) 17 provides a second input to the three input AND gate 16 while division codes D^{k}₀ to D^{k}ₙ₋₁ (D^{k}_{<0,n-1>}) 18 of implementing division code word D^{k}={Dₙ, Dₙ₋₁, Dₙ₋₂ . . . D₂, D₁, D₀} 19 provide the third input signal (the significance of implementing division code words 19 on the operation of the fractional-n frequency divider 7 is described in further detail below). As will be appreciated by those skilled in the art, it is only when all of the inputs to the three input AND gate 16 are logic high that the corresponding output signal is also logic high.

An XOR gate 20 then compares the output of three input AND gate 16 and a division code signal (D^{k}ₙ) 21 input signal so to produce the “hold” signal 15 that acts as a toggle signal for the feedback multiplexer 14.

The Fₒᵤₜ signal 5, is produced by an output multiplexer 22 which employs a “polarity” signal 23 to toggle between the outputs of an a-channel, when the “polarity” signal 23 is logic low, and a b-channel, when the “polarity” signal 23 is logic high. The input to the a-channel and the b-channel of the output multiplexer 22 is a clock signal (Clkₙ) 24 and an inverted clock signal (/Clkₙ) 25, respectively, generated by the nth ⅔ divider cell 3.

The insert of FIG. 2 presents the circuitry 26 employed to generate the “polarity” signal 23. This circuitry 26 comprises first and second two input AND gates 27 and 28 that provide an a-channel input and a b-channel input, respectively, to a polarity circuit multiplexer 29. An inverted “hold” signal (/hold) 30 is employed to switch the output of the polarity circuit multiplexer 29. When the inverted hold signal 30 is logic low the output is provided via the a-channel and this switches to the b-channel when the inverted hold signal 30 toggles to logic high. The output of the polarity circuit multiplexer 29 then acts as a single input to a D-latch 31 that is clocked by an inverted n−1 divider cell output signal (/Clkₙ₋₁) 32.

The inputs to the first AND gate 27 is the “polarity” signal 23 fed back from the output of the D-latch 31 and the inverted division code signal (/D^{k}ₙ) 17. The inverted division code signal (/D^{k}ₙ) 17 and the clock signal (Clkₙ) 24 provide the inputs for the second AND gate 28. This arrangement of the circuitry 26 results in the “polarity” signal flopping on the negative edge of the n−1 divider cell output signal (Clkₙ₋₁) 33 when the hold signal is logic low. However, flopping of the “polarity” signal is prevented when the “hold” signal 15 is logic high. The significance of this arrangement will become apparent to the skilled reader from the following described implementations of the fractional-n frequency divider 7.

### Eight Cell Fractional-n Frequency Divider

Let us consider a fractional-n frequency divider 7 comprising a total of eight ⅔ divider cells 3. The implementing division code word 19 is then required to take the form:

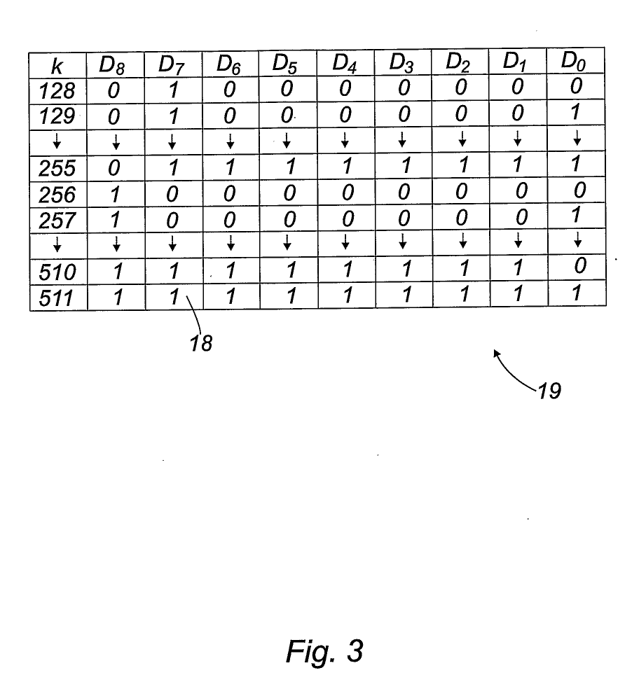

D^{k}={D₈, D₇, D₆, D₅, D₄, D₃, D₂, D₁, D₀} (6)

where each of the individual division codes 18 are set to logic high or logic low depending on the integer division value k desired. FIG. 3 presents a table of division code words 19 for a number of configurations of the fractional-n frequency divider of FIG. 2 selected for illustrative purposes, namely for k equals 128, 129, 255, 256, 257, 510 and 511.

### 128-129 Configuration

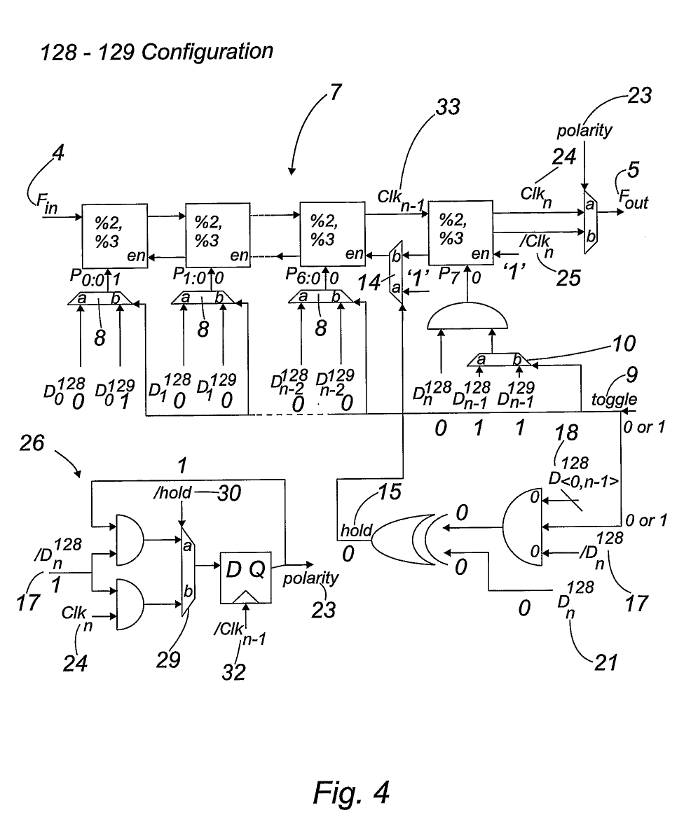

In FIG. 4, the fractional-n frequency divider 7 is configured such that the a-channels of multiplexers 8 and the first nth divider multiplexer 10 receive the divisional codes 18 corresponding to divisional code word D¹²⁸, while the b-channels receive the divisional codes 18 corresponding to divisional code word D¹²⁹.

When the toggle signal 9 is set to logic low i.e. ‘0’ the transmitted clock signals (p₇, p₆, p₅, p₄, p₃, p₂, p₁, p₀) all are set to ‘0’. In this configuration the “hold” signal 15 is always set to ‘0’ such that the ripple feedback to the n−1 divider cell 3 is set to logic high via the a-channel of the feedback multiplexer 14 and the “polarity” signal 23 simply flops on the negative edge of the n−1 divider cell output signal (Clkₙ₋₁) 33, as previously described.

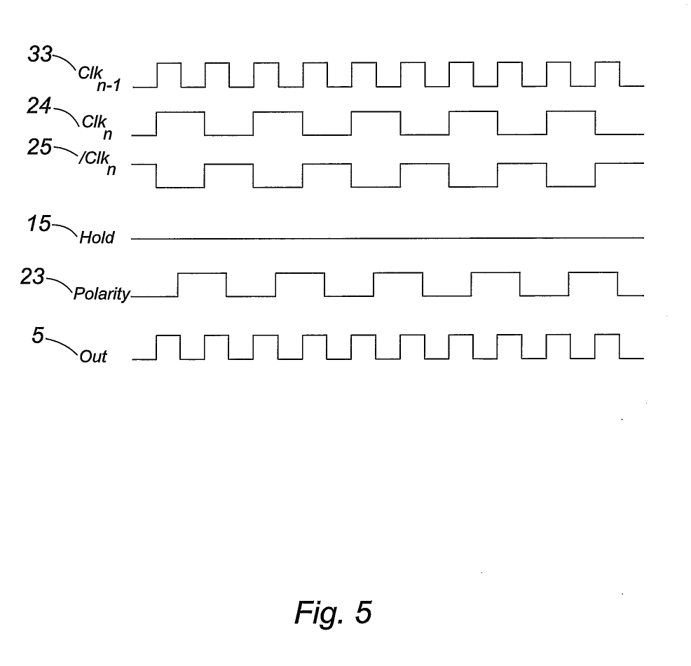

FIG. 5 presents a general schematic timing diagram for the signals of the fractional-n frequency divider 7 of FIG. 2 configured to provide an output that corresponds to F_{In}/k where k is an integer between 2ⁿ⁻¹ and 2ⁿ⁻1. In particular, FIG. 5 presents schematic representations of the Clkₙ₋₁ signal 33, Clkₙ signal 24, /Clkₙ signal 25, “hold” signal 15, “polarity” signal 23 and Fₒᵤₜ signal 5. Importantly, the timing of the flopping of the “polarity” signal 23 acts to combine the Clkₙ signal 24 and the /Clkₙ signal 25 so as to generate the Fₒᵤₜ signal 5 which replicates the Clkₙ₋₁ signal 33. In the present example this effectively corresponds to the output from seven ⅔ divisional divider cells 3 each set to divide by 2 i.e. a division by 128.

When the toggle signal 9 is set to logic high i.e. ‘1’ the transmitted clock signals (p₇, p₆, p₅, p₄, p₃, p₂, p₁) are all set to ‘0’ while clock signal p₀ is set to ‘1’. As for the previous example, the “hold” signal 15 is again always set to ‘0’ such that the ripple feedback to the n−1 divider cell 3 is set to logic high via the a-channel of the feedback multiplexer 14 and the “polarity” signal 23 simply flops on the negative edge of the n−1 divider cell output signal (Clkₙ₋₁) 33. The schematic timing diagram of FIG. 5 is again applicable with the generated Fₒᵤₜ signal 5 again replicating the Clkₙ₋₁ signal 33. In this particular example, this effectively corresponds to the output from seven ⅔ divisional divider cells 3 configured to provide division by 129.

Fractional division ratios between 128 and 129 are simply achieved by the employment of the toggle signal 9 so as to effectively toggle between the divisional codes 18 corresponding to divisional code words D¹²⁸ and D¹²⁹. For example, an equal weighting between divisional code words D¹²⁸ and D¹²⁹ provides fractional division by 128.5, a weighting ratio D¹²⁸:D¹²⁹ of 3:1 will provide for division by 128.25, while a weighting ratio D¹²⁸:D¹²⁸ of 1:3 will provide for division by 128.75.

### 255-256 Configuration

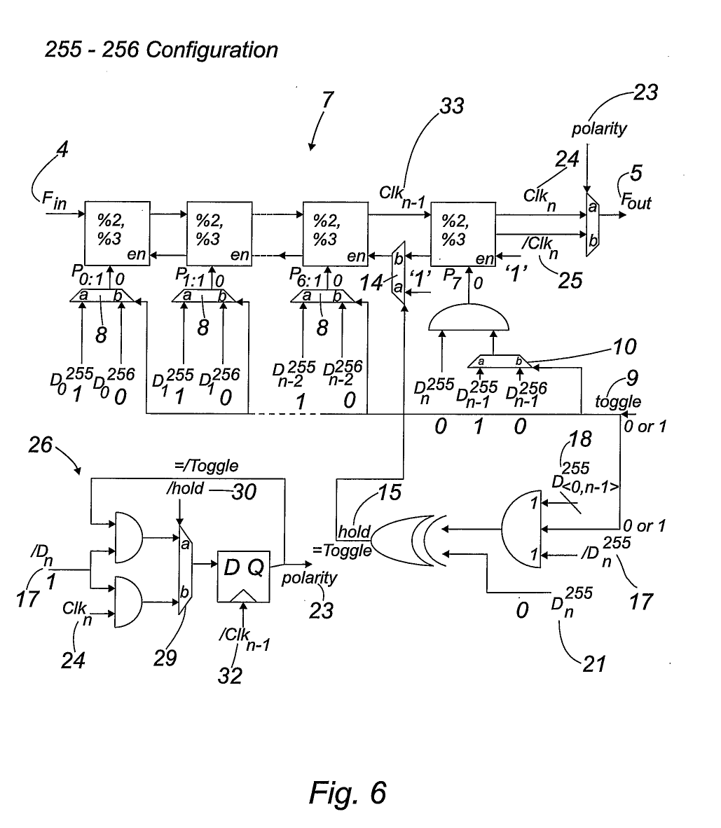

Now let us consider the arrangement presented in FIG. 6 where the fractional-n frequency divider 7 is configured such that the a-channels of multiplexers 8 and the first nth divider multiplexer 10 receive the divisional codes 18 corresponding to divisional code word D²⁵⁵, while the b-channels receive the divisional codes 18 corresponding to divisional code word D²⁵⁶.

When the toggle signal 9 is set to logic low i.e. ‘0’ the transmitted clock signals (p₆, p₅, p₄, p₃, p₂, p₁, p₀) are all set to ‘1’ while p₇ is set to ‘0’. As with the previous examples, the “hold” signal 15 is again always set to ‘0’ such that the ripple feedback to the n−1 divider cell 3 is set to logic high via the a-channel of the feedback multiplexer 14 and the “polarity” signal 23 simply flops on the negative edge of the n−1 divider cell output signal (Clkₙ₋₁) 33. The schematic timing diagram of FIG. 5 is again applicable with the generated Fₒᵤₜ signal 5 again effectively replicating the Clkₙ₋₁ signal 33. This effectively corresponds to the output from seven ⅔ divisional divider cells 3, each being clocked by a logic high signal i.e. configured to provide division by 255.

The situation changes however when the toggle signal 9 is set to logic high i.e. ‘1’. The transmitted clock signals (p₇, p₆, p₅, p₄, p₃, p₂, p₁, p₀) are now all set to ‘0’. Importantly, the “hold” signal 15 is now set to ‘1’ such that the ripple feedback to the n−1 divider cell 3 is now provided directly by the nth divider cell 3. Since the “hold” signal 15 is now set to ‘1’ the “polarity” signal 23 is provided via the a-channel of the polarity circuit multiplexer 29. This results in the “polarity” signal 23 effectively being set equal to the value of the inverted “hold” signal i.e. logic low. As a result the Fₒᵤₜ signal 5 now simply replicates the Clkₙ signal 24. The Fₒᵤₜ signal 5 therefore corresponds to the output from eight ⅔ divisional divider cells 3 each set to divide by 2 i.e. a division by 256.

Fractional division ratios between 255 and 256 are again achieved by the employment of the toggle signal 9 so as to effectively toggle between the two configurations described above where divisional codes 18 corresponding to divisional code words D²⁵⁵ and D²⁵⁶ are employed.

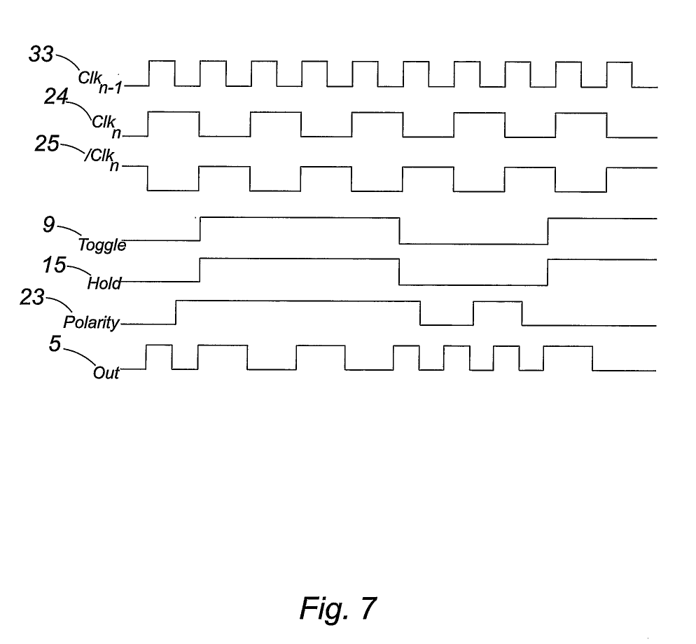

FIG. 7 presents a general schematic timing diagram for the signals of the fractional-n frequency divider 7 of FIG. 2 configured to provide an output that corresponds to Fᵢₙ/255.x. In particular, schematic representations of the Clkₙ₋₁ signal 33, Clkₙ signal 24, /Clkₙ signal 25, “toggle” signal 9, “hold” signal 15, “polarity” signal 23 and Fₒᵤₜ signal 5 are provided. The important point to note here is that when the “hold” signal 15 is logic low the timing of the flopping of the “polarity” signal 23 again acts to combine the Clkₙ signal 24 and the /Clkₙ signal 25 so as to generate the Fₒᵤₜ signal 5 which effectively replicates the Clkₙ₋₁ signal 33. However, when the “hold” signal 15 is logic high the “polarity” signal 23 is prevented from flopping and the Fₒᵤₜ signal 5 simply replicates the /Clkₙ si_{g}nal 25.

### 256-257 Configuration

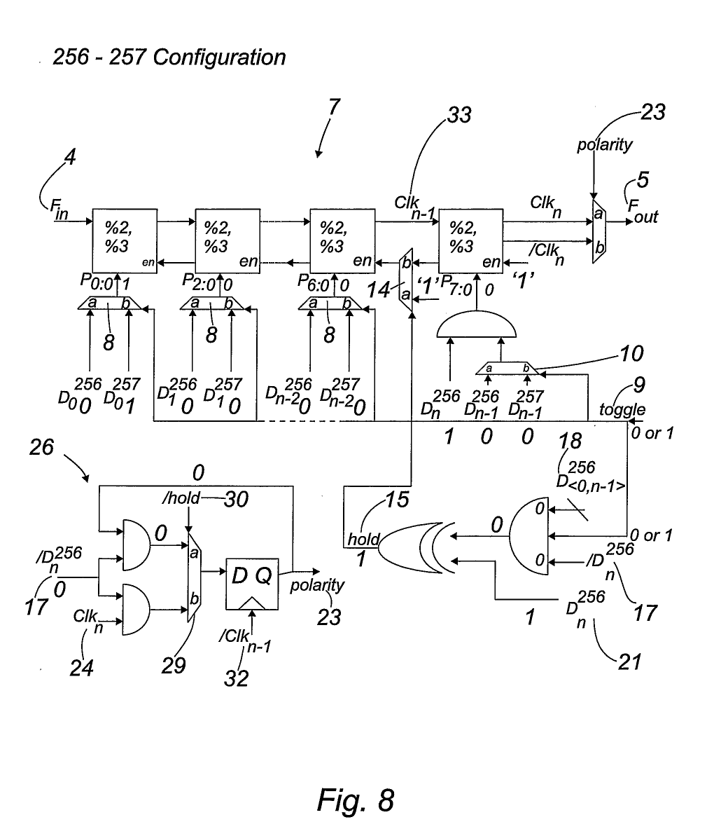

The arrangement presented in FIG. 8 corresponds to the fractional-n frequency divider 7 being configured such that the a-channels of multiplexers 8 and the first nth divider multiplexer 10 receive the divisional codes 18 corresponding to divisional code word D²⁵⁶, while the b-channels receive the divisional codes 18 corresponding to divisional code word D²⁵⁷.

When the toggle signal 9 is set to logic low i.e. ‘0’ the transmitted clock signals (p₇, p₆, p₅, p₄, p₃, p₂, p₁, p₀) are all set to ‘0’. In this configuration, the “hold” signal 15 is always set to ‘1’ such that the ripple feedback to the n−1 divider cell 3 is provided directly by the nth divider cell 3 and the “polarity” signal 23 is provided via the a-channel of the feedback multiplexer 14. As will be apparent to the skilled man, this is the same arrangement for the division by 256 configuration described above i.e. the Fₒᵤₜ signal 5 corresponds to the output from eight ⅔ divisional divider cells 3 each set to divide by 2.

When the toggle signal 9 is set to logic high i.e. ‘1’ the transmitted clock signal p₀ is now set to ‘1’ while clock signals (p₆, p₅, p₄, p₃, p₂, p₁, p₀) remain set to ‘0’. In this configuration, the “hold” signal 15 is again always set to ‘1’ such that the ripple feedback to the n−1 divider cell 3 is provided directly by the nth divider cell 3 and the “polarity” signal 23 is again provided via the a-channel of the feedback multiplexer 14. It follows that the Fₒᵤₜ signal 5 now simply replicates the Clkₙ signal 24 which for this configuration corresponds to the output from eight ⅔ divisional divider cells 3 arranged to provide an integer division by 257.

Fractional division ratios between 256 and 257 are again achieved by the employment of the toggle signal 9 so as to effectively toggle between the two configurations described above where divisional codes 18 corresponding to divisional code words D²⁵⁵ and D²⁵⁶ are employed.

### 510-511 Configuration

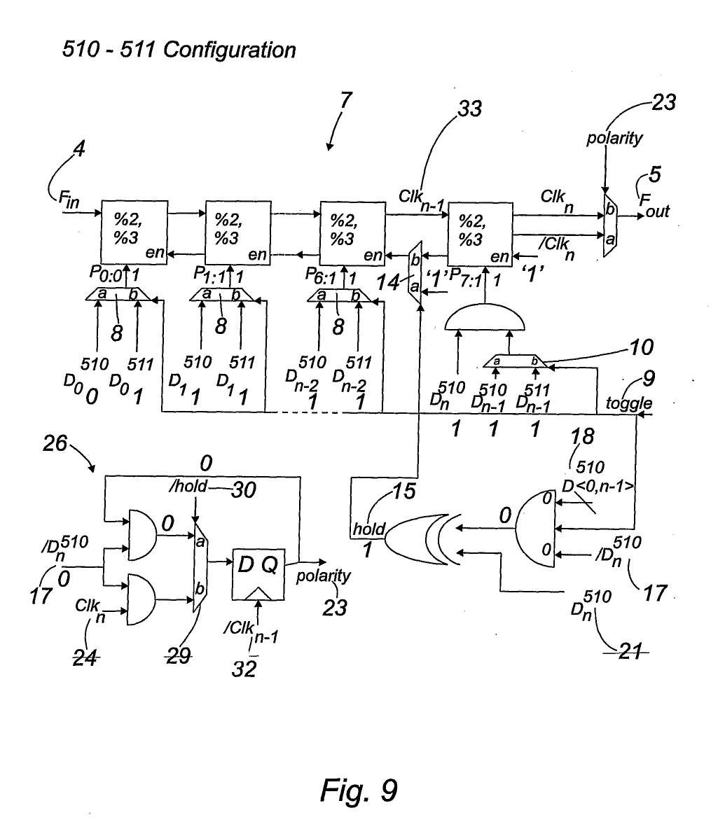

The arrangement presented in FIG. 9 corresponds to the fractional-n frequency divider 7 being configured such that the a-channels of multiplexers 8 and the first nth divider multiplexer 10 receive the divisional codes 18 corresponding to divisional code word D⁵¹⁰, while the b-channels receive the divisional codes 18 corresponding to divisional code word D⁵¹¹.

This arrangement is similar to the previously described 256-257 configuration. When the toggle signal 9 is set to logic low i.e. ‘0’ the transmitted clock signals (p₇, p₆, p₅, p₄, p₃, p₂, p₁) are all set to ‘1’ while p₀ is set to ‘0’. When the toggle signal 9 is set to logic high i.e. ‘1’, the transmitted clock signals (p₇, p₆, p₅, p₄, p₃, p₂, p₁, p₀) are all set to ‘1’. In both configurations the “hold” signal 15 is always set to ‘1’ such that the ripple feedback to the n−1 divider cell 3 is provided directly by the nth divider cell 3. The “polarity” signal 23 is always set equal to logic low such that the Fₒᵤₜ signal 5 now simply replicates the Clkₙ signal 24. The fractional-n frequency divider 7 thus now simply acts as an eight, ⅔ cell 3 divider configured to either dived by 510 or 511, depending on the value of the toggle signal 9.

Control of the toggle signal 9 thus allows for fractional divisional values between 510 and 511 to be obtained in a similar manner to that described above.

### General Remarks

From the above description, and detailed worked examples, it can be seen that the fractional-n frequency divider 7 provides a means for extending the range of divisional values produced by n ⅔ divider cells 3 between a minimum and maximum value provided by the following expressions:

Minimum division ratio=2⁻¹ (7)

Maximum division ratio=2ⁿ⁺¹−1 (8)

where n in an integer greater than or equal to 2. i.e. for eight ⅔ divider cells 3 the range extends between 128 and 511.

Importantly, this divisional range is achieved with no “dead zones” being present such that all fractional values can be obtained with this range.

In addition, by taking the Fₒᵤₜ output signal 5 from the nth ⅔ divider cell, and not from between the first and second divider cells 3, as with some of the previously described prior art systems, avoids the Fₒᵤₜ output signal 5 being inherently susceptible to detrimental harmonics and fractional spurious tones induced through the toggling process.

The foregoing description of the invention has been presented for purposes of illustration and description and is not intended to be exhaustive or to limit the invention to the precise form disclosed. The described embodiments were chosen and described in order to best explain the principles of the invention and its practical application to thereby enable others skilled in the art to best utilise the invention in various embodiments and with various modifications as are suited to the particular use contemplated. Therefore, further modifications or improvements may be incorporated without departing from the scope of the invention as defined by the appended claims.

1. A fractional-n frequency divider comprising:
n divider cells connected so as to form a ripple counter, n being an integer greater than or equal to two;
an output multiplexer that is provided with a clock signal (Clkₙ,) and an inverted clock signal (/Clkₙ) by the nth divider cell;
a polarity circuit that provides a means for generating a polarity signal; and
wherein the polarity signal is employed to clock the output multiplexer so as to controllably combine clock signal (Clkₙ) and an inverted clock signal (/Clkₙ) to produce an output signal (Fₒᵤₜ).

2. A fractional-n frequency divider as defined in claim 1, wherein the polarity circuit comprises a latch, the latch having a first configuration whereby the clock signal (Clkₙ) is provided as an input signal and the clock signal output from the n−1 divider cell (Clkₙ₋₁) is provided as a latch clocking signal.

3. A fractional-n frequency divider as defined in claim 2, wherein the latch is clocked by an inverted clock signal output from the n−1 divider cell (/Clkₙ₋₁).

4. A fractional-n frequency divider as defined in claim 1, further comprising a feedback multiplexer located within the feedback link between the nth divider cell and the n−1 divider cell, wherein the feedback multiplexer provides a means for switching the fractional-n frequency divider between a first configuration in which the feedback to the n−1 divider cell is set to logic high, and a second configuration in which the feedback to the n−1 divider cell is provided by the nth divider cell.

5. A fractional-n frequency divider as defined in claim 2, wherein the polarity circuit further comprises a polarity circuit multiplexer, wherein the polarity circuit multiplexer provides a means for switching polarity circuit from the first configuration to a second configuration, wherein the polarity signal is fed back to provide the input signal to the latch.

6. A fractional-n frequency divider as defined in claim 5, wherein the polarity circuit further comprises a first and second polarity AND gates configured to provide a first and second input to the polarity circuit multiplexer.

7. A fractional-n frequency divider as defined in claim 1, wherein the fractional-n frequency divider further comprises a hold circuit that provides a means for generating a hold signal that is employed to control the configuration of the polarity circuit.

8. A fractional-n frequency divider as defined in claim 7, wherein the hold signal is also employed to control the configuration of the fractional-n frequency divider via the feedback multiplexer.

9. A fractional-n frequency divider as defined in claim 1, wherein the fractional-n frequency divider further comprises a multiplexer associated with each of the n divider cells wherein the multiplexers provide a means of switching between at least two clock signals for the associated n divider cells.

10. A fractional-n frequency divider as defined in claim 9, further comprising an nth divider cell AND gate located between the nth divider cell and its associated multiplexer.

11. A fractional-n frequency divider as defined in claim 10, wherein the fractional-n frequency divider is provided with at least two implementing division code words, D^{k-1} and D^{k}, which determine a first and a second integer division configuration of the fractional-n frequency divider.

12. A fractional-n frequency divider as defined in claim 11, wherein each implementing division code word comprises divisional code signals Dₙ, Dₙ₋₁, Dₙ₋₂ . . . D₂, D_{1, and D}₀.

13. A fractional-n frequency divider as defined in claim 12, wherein first and second inputs to each of the multiplexers associated with n divider cells are provided with divisional code signals D^{k-1}_{n-1′} and D^{k}ₙ₋₁, respectively.

14. A fractional-n frequency divider as defined in claim 13, wherein a first and second input to the nth divider cell AND gate is provided by divisional code signal D^{k}ₙ and the output of the multiplexer associated with the nth divider cell, respectively.

15. A fractional-n frequency divider as defined in claim 14, wherein a toggle signal is employed to control the settings of the multiplexer associated with each n divider cells.

16. A fractional-n frequency divider as defined in claim 8, wherein the hold circuit comprises an XOR gate having a first input provided by a three input AND Gate and a second input provided by divisional code signal D^{k}ₙ.

17. A fractional-n frequency divider as defined in claim 16, wherein the inputs to the three input AND Gate comprises divisional code signals D^{k}₀ to D^{k}ₙ₋₁, the toggle signal and an inverted divisional code signal D^{k}ₙ (/D^{k}ₙ).

18. A fractional-n frequency divider as defined in claim 11, wherein the first polarity AND gate is provided with a first input corresponding to the polarity signal and a second input corresponding to the inverted divisional code signal D^{k}ₙ (/D^{k}ₙ).

19. A fractional-n frequency divider as defined in claim 18, wherein the second polarity AND gate is provide with a first input corresponding to the clock signal (Clkₙ) and a second input corresponding to the inverted divisional code signal D^{k}ₙ (/D^{k}ₙ).

20. A method of frequency dividing a signal Fᵢₙ, the method comprising the steps of:
1) passing the signal Fᵢₙ through n divider cells connected so as to form a ripple counter;
2) generating a clock signal (Clkₙ) and an inverted clock signal (/Clkₙ) from the nth divider cell; and
3) producing an output signal Fₒᵤₜ by controllably combining the clock signal (Clkₙ) and the inverted clock signal (/Clkₙ).

21. A method of frequency dividing a signal as defined in claim 20, wherein the step of producing the output signal Fₒᵤₜ comprises the steps of:
1) providing a logic high feedback between the nth and n−1 divider cells; and
2) flopping between the clock signal (Clkₙ) and the inverted clock signal (/Clkₙ) in response to a clock signal generated by an output from a n−1 divider cell (Clkₙ₋₁) .

22. A method of frequency dividing a signal as defined in claim 21, wherein the step of flopping between the clock signal (Clkₙ) and the inverted clock signal (/Clkₙ) occurs in response to the negative edge of the clock signal output from the n−1 divider cell (Clkₙ₋₁).

23. A method of frequency dividing a signal as defined in claim 20, wherein the step of producing the output signal Fₒᵤₜ comprises the steps of:
3) providing a feedback link to the n−1 divider cell directly from the nth divider cell; and
4) preventing flopping between the clock signal (Clkₙ) and the inverted clock signal (/Clkₙ).

24. A method of frequency dividing a signal as defined in claim 20, further comprising the step of providing at least two implementing division code words, D^{k-1} and D^{k}, which determine a first and a second integer division configuration of the fractional-n frequency divider.

25. A method of frequency dividing a signal as defined in claim 24, further comprising the step of toggling between the first and the second integer division configuration of the fractional-n frequency divider.
